(19) United States
(12) Patent Application Publication
(10) Pub. No.: US 2016/0294358 A1
(43) Pub. Date: Oct. 6, 2016

(54) ACOUSTIC WAVE FILTER, DUPLEXER, AND MODULE

(71) Applicant: TAIYO YUDEN CO. LTD., Tokyo (JP)

(72) Inventor: Satoru ONO, Tokyo (JP)

(73) Assignee: TAIYO YUDEN CO. LTD., Tokyo (JP)

(21) Appl. No.: 15/058,847

(22) Filed: Mar. 2, 2016

(30) Foreign Application Priority Data
Mar. 31, 2015 (JP) 2015-073596

(51) Int. Cl. H03H 9/70; H03H 9/54

(52) U.S. Cl. CPC H03H 9/547; H03H 9/706

(57) ABSTRACT

A filter including: a substrate; an input pad; an output pad; a ground pad; a plurality of first acoustic wave resonators formed on the substrate, and connected in series between the input pad and the output pad; a plurality of second acoustic wave resonators, each comprising: a piezoelectric film on the substrate; a lower electrode between the substrate and the piezoelectric film, connected to the ground pad; and a upper electrode on the piezoelectric film, and connected between an adjacent pair of the first acoustic wave resonators or between one of the plurality of first acoustic wave resonators and one of the input and the output pad.

### CROSS-REFERENCE TO RELATED APPLICATION

This application is based upon and claims the benefit of priority of the prior Japanese Patent Application No. 2015-073596, filed on Mar. 31, 2015, the entire contents of which are incorporated herein by reference.

### FIELD

A certain aspect of the present invention relates to an acoustic wave filter, a duplexer, and a module.

### BACKGROUND

Bulk Acoustic Wave filters, which use a piezoelectric thin film resonator, are employed as filters used in communication devices such as mobile phones. A duplexer including two or more filters and a module including two or more filters are sometimes embedded in the communication device.

The filter is required to have frequency characteristics of low loss in the passband and high suppression outside the passband. The low-loss frequency characteristics allow communication devices to reduce their electrical power consumption and to improve speech quality. To increase the degree of suppression outside the passband, a structure is known in which parallel resonators located in the parallel arm of a ladder-type filter are connected to a ground through a common line connected to each of a parallel resonators as disclosed in Japanese Patent Application Publication No. 2003-298392 (Patent Document 1). Moreover, a structure is known in which all lower electrodes are grounded through a device that ensures RF insulation in a filter using a piezoelectric thin film resonator as disclosed in Japanese Patent Application Publication No. 2012-19515.

However, the method disclosed in Patent Document 1 still leaves room for improvement in increasing the degree of suppression across wide frequencies outside the passband.

### SUMMARY OF THE INVENTION

According to an aspect of the present invention, it is an object to improve a suppression of frequencies outside the passband.

According to another aspect of the present invention, there is provided a filter including: a substrate; an input pad; an output pad; a ground pad; a plurality of first acoustic wave resonators formed on the substrate, and connected in series between the input pad and the output pad; a plurality of second acoustic wave resonators, each including: a piezoelectric film on the substrate; a lower electrode between the substrate and the piezoelectric film, connected to the ground pad; and a upper electrode on the piezoelectric film, and connected between an adjacent pair of the first acoustic wave resonators or between one of the plurality of first acoustic wave resonators and one of the input and the output pad.

### BRIEF DESCRIPTION OF THE DRAWINGS

FIG. 1 is a circuit diagram of an acoustic wave filter in accordance with a first embodiment;

FIG. 2 is a plan view of the acoustic wave filter of the first embodiment;

FIG. 3 is a cross-sectional view taken along line A-A in FIG. 2;

FIG. 4 is a plan view of an acoustic wave filter in accordance with a first comparative example (prior art);

FIG. 5 illustrates results of pass characteristics in a first experiment;

FIG. 6 illustrates results of pass characteristics in a second experiment;

FIG. 7 is a cross-sectional view of a first variation of a series resonator and a parallel resonator;

FIG. 8 is a cross-sectional view of a second variation of the series resonator and the parallel resonator;

FIG. 9 is a block diagram of a duplexer in accordance with a second embodiment; and

FIG. 10 is a block diagram of a module in accordance with a third embodiment.

### DETAILED DESCRIPTION

Hereinafter, a description will be given of embodiments of the present invention with reference to the accompanying drawings.

### First Embodiment

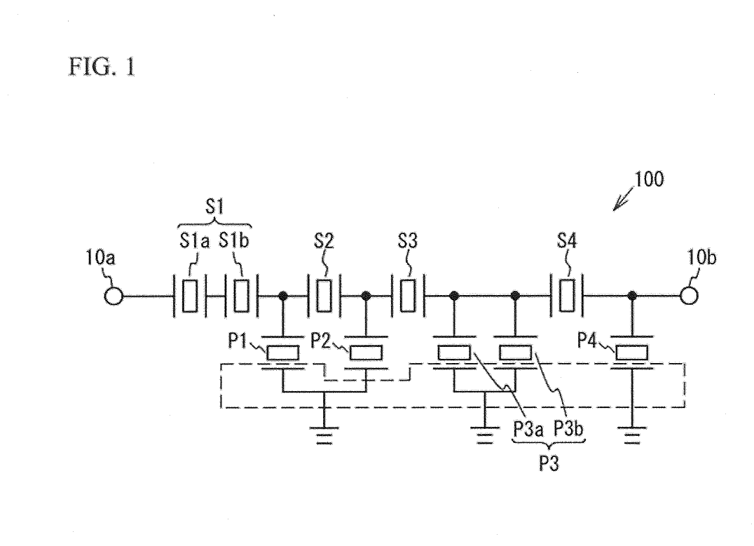

FIG. 1 is a circuit diagram of an acoustic wave filter in accordance with a first embodiment. An acoustic wave filter 100 of the first embodiment is a ladder-type filter that includes one or more series resonators S1 through S4 connected in series between an input terminal 10a and an output terminal 10b and one or more parallel resonators P1 through P4 connected in parallel between the input terminal 10a and the output terminal 10b as illustrated in FIG. 1. The series resonator S1 includes resonators S1a and S1b connected in series with each other. The parallel resonator P3 includes resonators P3a and P3b connected in parallel with each other. The series resonators S1 through S4 and the parallel resonators P1 through P4 are piezoelectric thin film resonators, which will be described in detail later.

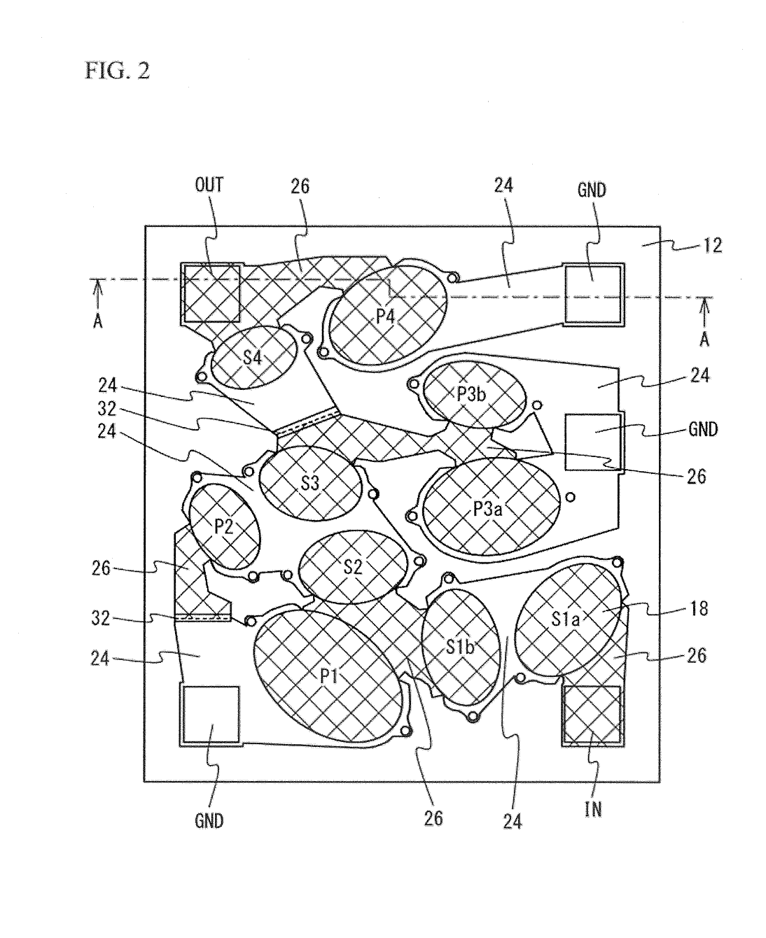

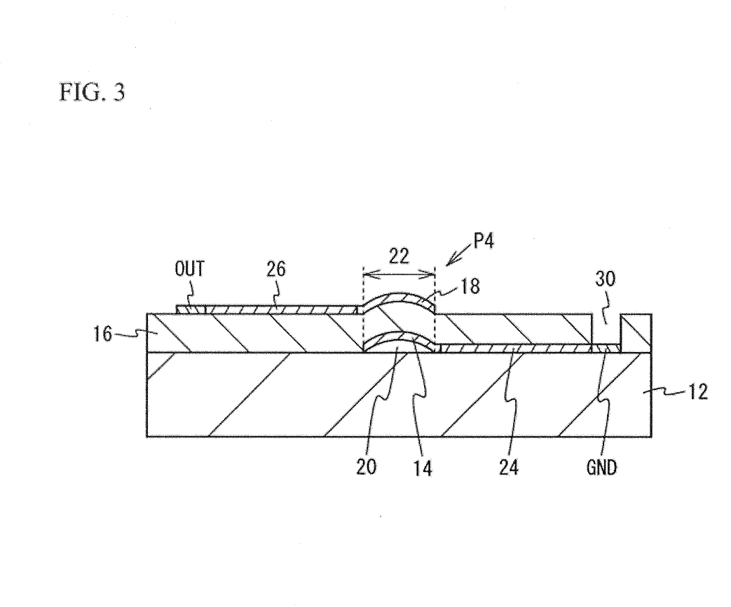

FIG. 2 is a plan view of the acoustic wave filter of the first embodiment. FIG. 3 is a cross-sectional view taken along line A-A in FIG. 2. FIG. 2 illustrates, by omitting a piezoelectric film 16, a semiconductor substrate 12, and lower wiring lines 24. In FIG. 2, components located further up than the piezoelectric film 16 are shown with cross hatching, and component located lower than the piezoelectric film 16 are shown without hatching.

The acoustic wave filter 100 of the first embodiment includes the series resonators S1 through S4 and the parallel resonators P1 through P4 formed on the semiconductor substrate 12 such as silicon as illustrated in FIG. 2. The series resonators S1 through S4 are connected in series between an input pad IN and an output pad OUT. The parallel resonators P1 through P4 are connected in parallel between the input pad IN and the output pad OUT.

As illustrated in FIG. 3, the parallel resonator P4 includes a lower electrode 14 located on the semiconductor substrate 12 so that an air gap 20 having a dome-shaped bulge is formed between the upper surface of the semiconductor substrate 12 and the lower electrode 14. The lower electrode 14 is electrically coupled to the semiconductor substrate 12. That is to say, the lower electrode 14 is located to make direct contact with the upper surface of the semiconductor substrate 12, for example. The dome-shaped bulge is a bulge having a shape in which the height of the air gap 20 is low in the periphery of the air gap 20 and the height of the air gap 20 increases at closer distance to the center of the air gap 20.

The piezoelectric film 16 is located on the lower electrode 14 and the semiconductor substrate 12. The piezoelectric film 16 may be an aluminum nitride film, a zinc oxide film, a lead zirconate titanate film, or a lead titanate film. An upper electrode 18 is located on the piezoelectric film 16, and has a region (a resonance region 22) that is facing the lower electrode 14 through the piezoelectric film 16. The resonance region 22 has an elliptical shape, and is a region in which an acoustic wave in a thickness extension mode excites. The shape of the resonance region 22 is not limited to an elliptical shape, and may be a polygonal shape.

The parallel resonator P4 is described with reference to FIG. 3, but the series resonators S1 through S4 and the parallel resonators P1 through P3 have a structure designed to have the lower electrode 14, the piezoelectric film 16, and the upper electrode 18 stacked as with the parallel resonator P4.

As illustrated in FIG. 2 and FIG. 3, the lower wiring line 24 and ground pads GND are located on the semiconductor substrate 12. The lower wiring lines 24 and the ground pads GND are electrically coupled to the semiconductor substrate 12. That is to say, the lower wiring lines 24 and the ground pads GND are located to make direct contact with the upper surface of the semiconductor substrate 12, for example. The piezoelectric film 16 covers the lower wiring lines 24, but does not cover the ground pads GND. An aperture 30 of the piezoelectric film 16 is formed over the ground pad GND, and enables electrical connection to the ground pad GND.

The lower electrode 14 and the lower wiring line 24 are simultaneously formed by deposition of a metal film and patterning of the metal film. Thus, the lower electrode 14 and the lower wiring line 24 are formed of the same material, and have virtually the same film thickness. The lower electrode 14 and the lower wiring line 24 may be made of a single-layer film of ruthenium, chrome, aluminum, titanium, copper, molybdenum, tungsten, tantalum, platinum, rhodium, or iridium, or a multilayered film of any combination thereof. The ground pad GND may be a metal film formed by stacking titanium and/or gold on the lower electrode 14, for example.

The input pad IN (not shown in FIG. 3), the output pad OUT, and upper wiring lines 26 are located on the piezoelectric film 16. The input pad IN is omitted because an arrangement of itself is the same as the output pad OUT in FIG. 2. The input pad IN and the output pad OUT are not electrically coupled to the semiconductor substrate 12. The upper wiring line 26 connecting to the input pad IN and the upper wiring line 26 connecting to the output pad OUT are not electrically coupled to the semiconductor substrate 12, either. That is to say, the input pad IN, the output pad OUT, the upper wiring line 26 connecting to the input pad IN, and the upper wiring line 26 connecting to the output pad OUT do not make direct contact with, for example, the semiconductor substrate 12. The upper electrode 18 and the upper wiring line 26 are simultaneously formed by deposition of a metal film and patterning of the metal film. Thus, the upper electrode 18 and the upper wiring line 26 are made of the same material, and have virtually the same film thickness. The upper electrode 18 and the upper wiring lines 26 may be made of a single-layer film of ruthenium, chrome, aluminum, titanium, copper, molybdenum, tungsten, tantalum, platinum, rhodium, or iridium, or a multilayered film of any combination thereof. The input pad IN and the output pad OUT may be a metal film formed by stacking titanium and/or gold on the upper wiring line 26. The output pad OUT and the input pad IN may be formed on the upper wiring 26, and may also be formed on the piezoelectric film 16 directly.

The input pad IN, the output pad OUT, and the ground pads GND are coupled to an external device via, for example, wires or bumps. Thus, the input pad IN corresponds to the input terminal 10a in FIG. 1, the output pad OUT corresponds to the output terminal 10b in FIG. 1, and the ground pads GND correspond to grounds in FIG. 1.

The upper electrode 18 of the series resonator S1a is coupled to the input pad IN via the upper wiring line 26. The lower electrodes 14, which are not illustrated in FIG. 2, of the series resonators S1a and S1b are interconnected via the lower wiring line 24. The upper electrodes 18 of the series resonators 81b and 82 and the parallel resonator P1 are interconnected via the upper wiring line 26. The lower electrode 14 of the parallel resonator P1 is coupled to the ground pad GND via the lower wiring line 24.

The lower electrodes 14 of the series resonators S2 and S3 and the parallel resonator P2 are interconnected via the lower wiring line 24. The upper electrode 18 of the parallel resonator P2 is coupled to the ground pad GND via the upper wiring line 26 and the lower wiring line 24. The upper electrodes 18 of the series resonator S3 and the parallel resonators P3a and P3b are interconnected via the upper wiring line 26. The upper electrodes 18 of the series resonator S3 and the parallel resonators P3a and P3b are coupled to the lower electrode 14 of the series resonator S4 via the upper wiring line 26 and the lower wiring line 24. The lower electrodes 14 of the parallel resonators P3a and P3b are coupled to the ground pad GND via the lower wiring line 24.

The upper electrodes 18 of the series resonator S4 and the parallel resonator P4 are coupled to the output pad OUT via the upper wiring line 26. The lower electrode 14 of the parallel resonator P4 is coupled to the ground pad GND via the lower wiring line 24.

As described above, the input pad IN is coupled to the upper electrode 18 of the series resonator S1a via only the upper wiring line 26. The output pad OUT is coupled to the upper electrodes 18 of the series resonator S4 and the parallel resonator P4 via only the upper wiring line 26. The parallel resonators P1 through P4 are coupled to the ground pad GND via at least the lower wiring line 24. That is to say, the electrodes and the wiring lines in a region indicated by the dashed line in FIG. 1 are formed of the lower electrode 14 and the lower wiring line 24.

A connection region 32 of the lower wiring line 24 and the upper wiring line 26 in FIG. 2 has a configuration in which an aperture 30 from which the lower wiring line 24 is exposed to the piezoelectric film 16 is formed, and a metal wiring line connecting the lower wiring line 24 exposed from the aperture to the upper wiring line 26 on the piezoelectric film 16 is formed. The connection region 32 is not limited to the aforementioned configuration, and may have other configurations (e.g., through-hole wiring) as long as the lower wiring line 24 is coupled to the upper wiring line 26.

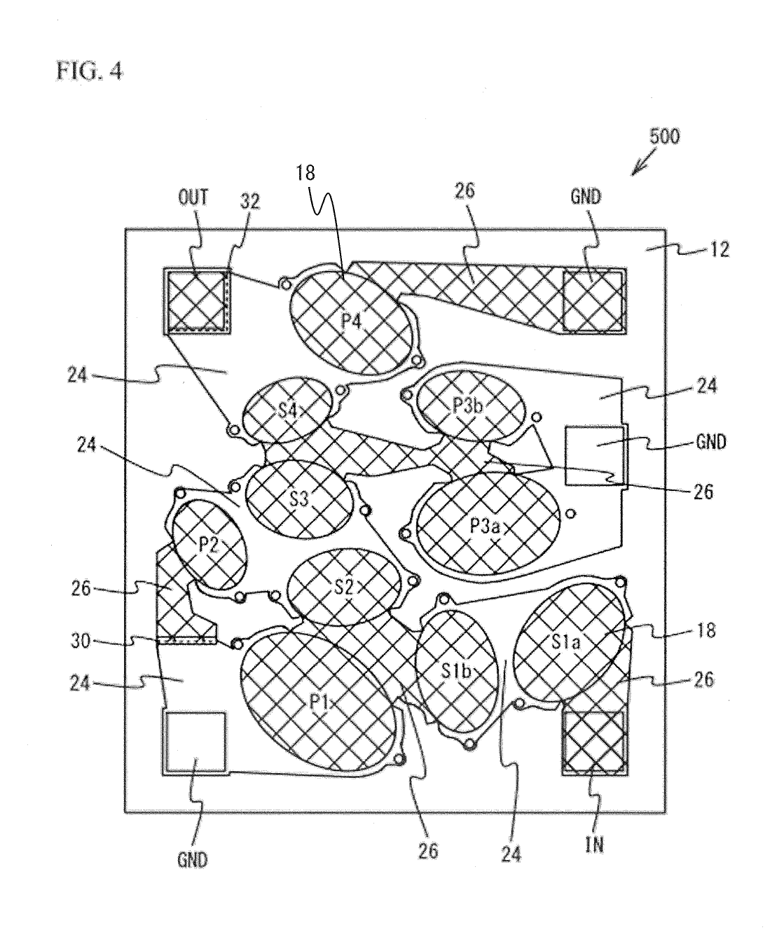

A description will next be given of an acoustic wave filter in accordance with a first comparative example (prior art). The circuit diagram of the acoustic wave filter of the first comparative example is the same as that of FIG. 1 of the first embodiment, and thus the illustration thereof is omitted. FIG. 4 is a plan view of an acoustic wave filter 500 in accordance with the first comparative example. In the acoustic wave filter 500 of the first comparative example, as illustrated in FIG. 4, the output pad OUT is coupled to the lower electrodes 14 of the series resonator S4 and the parallel resonator P4 via the lower wiring line 24. The upper electrode 18 of the series resonator S4 is coupled to the upper electrodes 18 of the series resonators S3 and the parallel resonators P3a and P3b via the upper wiring line 26. The upper electrode 18 of the parallel resonator P4 is coupled to the ground pad GND (shown as cross-hatched) located on the piezoelectric film 16 via the upper wiring line 26. As the output pad OUT is located on the piezoelectric film 16, the connection region 32 that connects the output pad OUT to the lower wiring line 24 is provided. Other configurations are the same as those of the first embodiment illustrated in FIG. 2, and thus the description is omitted. The structure of each resonator is the same as that of the first embodiment illustrated in FIG. 3, and thus the illustration is omitted.

Here, a description will be given of a first experiment conducted by the inventors. The inventors manufactured the acoustic wave filter 100 of the first embodiment and the acoustic wave filter 500 of the first comparative example, and measured the pass characteristics of both of them. The manufactured acoustic wave filter 100 of the first embodiment and the manufactured acoustic wave filter 500 of the first comparative example employed a multilayered film of a chrome film with a film thickness of 0.07 to 0.12 μm and a ruthenium film with a film thickness of 0.15 to 0.30 μm for the lower electrodes 14 and the lower wiring lines 24. An aluminum nitride film with a film thickness of 0.9 to 1.5 μm was used for the piezoelectric film 16. A multilayered film of a ruthenium film with a film thickness of 0.15 to 0.30 μm and a chrome film with a film thickness of 0.03 to 0.06 μm was used for the upper electrodes 18 and the upper wiring lines 26. This type of resonator can shift the frequency lower, by a mass loading effect. A multilayered film, of which the area is controlled by patterning, of a ruthenium film with a film thickness of 5 to 22 nm and a chrome film with a film thickness of 0.01 to 0.03 μm was located between the previously-mentioned ruthenium film and the previously-mentioned chrome film in the upper electrode 18 to adjust the frequency of each resonator. To adjust the frequency of the parallel resonator, a titanium film with a film thickness of 0.07 to 0.13 μm was located under the multilayered film of a ruthenium film and a chrome film for adjusting the frequency of the parallel resonator in the upper electrode 18. A silicon dioxide film with a film thickness of 0.05 to 0.11 μm was located on the uppermost layers of all the upper electrodes 18 to protect the electrode and to adjust the overall frequency.

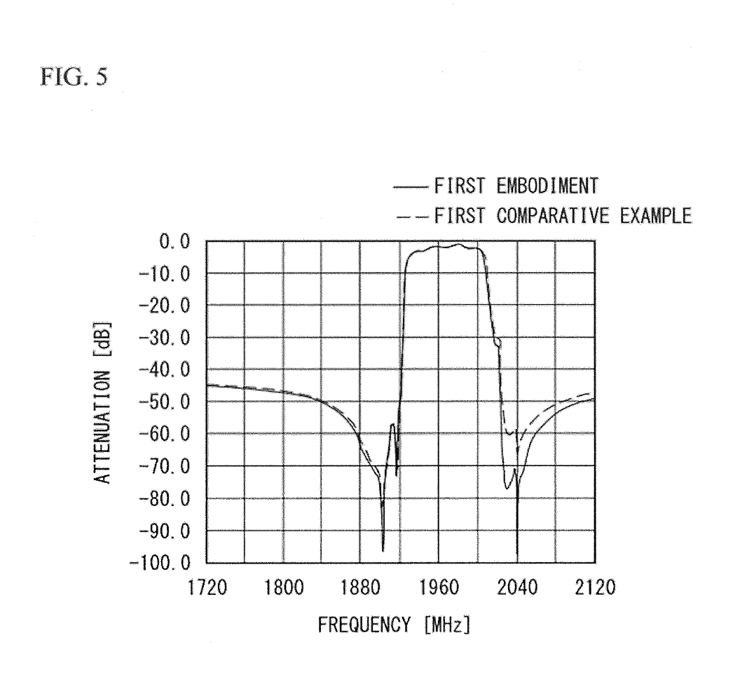

FIG. 5 illustrates results of pass characteristics in the first experiment. The solid line indicates the pass characteristics of the acoustic wave filter 100 of the first embodiment, and the dashed line indicates the pass characteristics of the acoustic wave filter 500 of the first comparative example. As illustrated in FIG. 5, the acoustic wave filter 100 of the first embodiment has virtually the same loss in the passband as that of the acoustic wave filter 500 of the first comparative example, but exhibits large attenuation across wide frequencies outside the passband compared to the acoustic wave filter 500 of the first comparative example.

A description will next be given of a second experiment conducted by the inventors. The inventors modified the acoustic wave filter 100 of the first embodiment and the acoustic wave filter 500 of the first comparative example so that the ground pad GND connected with the parallel resonator P4 becomes as a floating conductor by disconnecting the parallel resonator P4 from a ground to consider the parallel resonator P4 to be practically unprovided, and measured the pass characteristics of both of them.

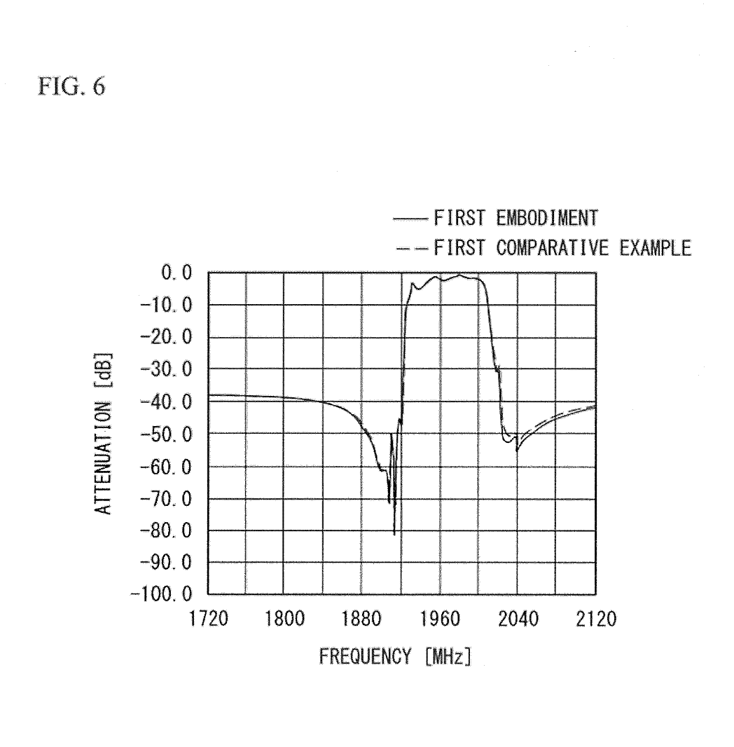

FIG. 6 illustrates results of pass characteristics in the second experiment. The solid line indicates the pass characteristics of the acoustic wave filter 100 of the first embodiment, and the dashed line indicates the pass characteristics of the acoustic wave filter 500 of the first comparative example. As illustrated in FIG. 6, even when the parallel resonator P4 is not practically connected, the acoustic wave filter 100 of the first embodiment slightly improves the attenuation outside the passband compared to the acoustic wave filter 500 of the first comparative example.

The first embodiment differs from the first comparative example in the following two points in the above-described first experiment.

(1) In the first embodiment, all the parallel resonators P1 through P4 are coupled to the ground pads GND located on the upper surface of the semiconductor substrate 12 via the lower wiring lines 24 located on the upper surface of the semiconductor substrate 12. On the other hand, in the first comparative example, the parallel resonator P4 is coupled to the ground pad GND located on the piezoelectric film 16 via the upper wiring line 26 located on the piezoelectric film 16.

(2) In the first embodiment, the output pad OUT is coupled to the series resonator S4 and the parallel resonator P4 via the upper wiring line 26, whereas in the first comparative example, the output pad OUT is coupled to the series resonator S4 and the parallel resonator P4 via the lower wiring line 24.

In the above-described second experiment, the first embodiment differs from the first comparative example in the aforementioned point (2).

Thus, the results of the first and second experiments reveal that the degree of suppression is improved across wide frequencies outside the passband by coupling all the parallel resonators P1 through P4 to the ground pads GND via the lower wiring lines 24. This is because the lower wiring line 24 is electrically coupled to the semiconductor substrate 12 and thereby the semiconductor substrate 12 can be practically used as a ground, to stabilize the ground potential on the semiconductor substrate 12. As a result, it is considered that the degree of suppression improves across wide frequencies outside the passband.

The degree of suppression outside the passband is also improved by coupling the output pad OUT to the series resonator S4 and the parallel resonator P4 via only the upper wiring line 26. This is considered to be because signals propagate to the semiconductor substrate 12 when the output pad OUT is coupled to the lower wiring line 24, negatively affecting the stabilization of the ground potential. In contrast, when the output pad OUT is coupled to only the upper wiring line 26, signals are prevented from propagating to the semiconductor substrate 12, and thus the ground potential is stabilized, and thereby the degree of suppression outside the passband is considered to improve.

As described above, in the first embodiment, all the parallel resonators P1 through P4 are coupled to the ground pads GND via the lower wiring lines 24 electrically coupled to the semiconductor substrate 12 as illustrated in FIG. 2. This configuration allows stabilization of the ground potential, and thereby allows the degree of suppression to improve across wide frequencies outside the passband as described in FIG. 5 and FIG. 6.

Moreover, as illustrated in FIG. 2 and FIG. 3, all the ground pads GND are located to make contact with the upper surface of the semiconductor substrate 12, and thus the ground potential can be effectively stabilized by using the semiconductor substrate 12 as a ground.

Moreover, as illustrated in FIG. 2, the input pad IN is coupled to the series resonator S1a via only the upper wiring line 26, and the output pad OUT is coupled to the series resonator S4 and the parallel resonator P4 via only the upper wiring line 26. This configuration prevents signals from propagating to the semiconductor substrate 12, and thus stabilizes the ground potential, improving the degree of suppression outside the passband as described in FIG. 5 and FIG. 6.

Moreover, to couple all the parallel resonators P1 through P4 to the ground pads GND via the lower wiring lines 24 as illustrated in FIG. 2, at least one parallel resonator P2 is preferably coupled to the ground pad GND via the upper wiring line 26 and the lower wiring line 24. In the configuration illustrated in FIG. 2, the lower wiring line 24 connecting to the series resonators S2 and S3 may be coupled to the upper wiring line 26 of the parallel resonator P2 through the connection region 32 to couple the parallel resonator P2 to the ground pad GND through the lower wiring line 24.

The first embodiment describes a case where the semiconductor substrate 12 is a silicon substrate as an example, but the semiconductor substrate 12 may be other semiconductor substrates. In addition, the semiconductor substrate 12 may be doped with an n-type dopant or a p-type dopant.

The first embodiment describes a case where two or more ground pads GND are located on the semiconductor substrate 12 as an example. However, a single ground pad GND connected to all the parallel resonators P1 through P4 may be provided.

The first embodiment describes a case where the acoustic wave filter is a ladder-type filter as an example, but the acoustic wave filter may be other filters such as a lattice-type filter.

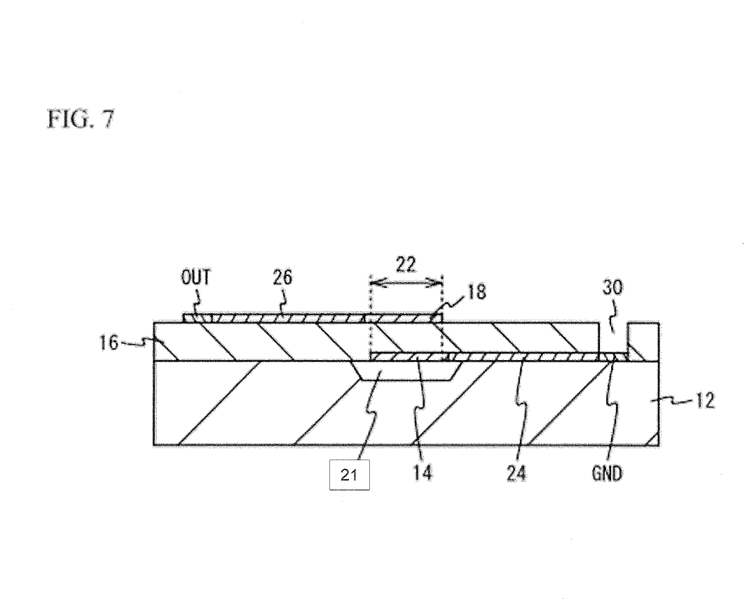

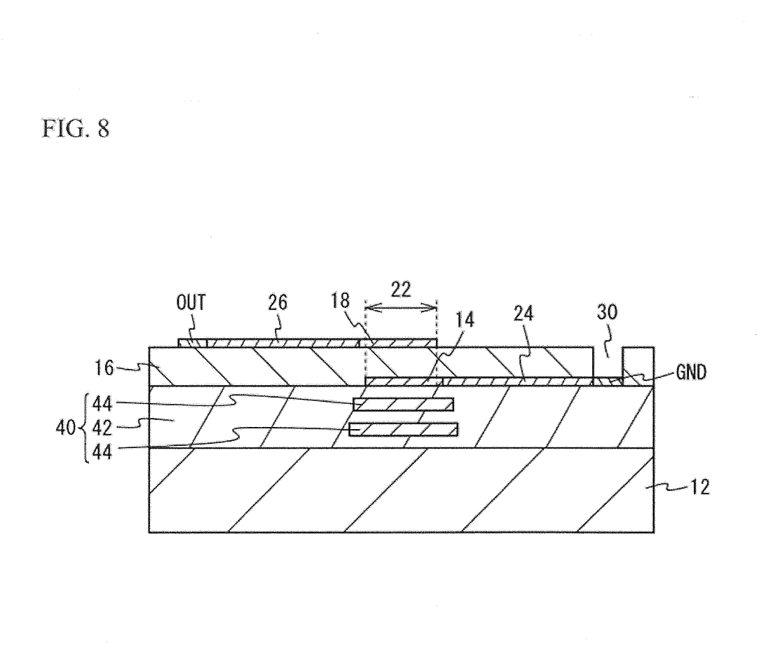

The first embodiment describes a case where the air gap 20 having a dome-shaped bulge is formed between the upper surface of the flat semiconductor substrate 12 and the lower electrode 14 in the series resonators S1 through S4 and the parallel resonators P1 through P4 as illustrated in FIG. 3 as an example, which is not intended to limit the invention in any way. FIG. 7 is a cross-sectional view of a first variation of the series resonator and the parallel resonator, and FIG. 8 is a cross-sectional view of a second variation of the series resonator and the parallel resonator. FIG. 7 and FIG. 8 are cross-sectional views corresponding to the cross section taken along line A-A in FIG. 2.

As illustrated in FIG. 7, the series resonator and the parallel resonator may have a recessed portion 21 formed in the upper surface of the semiconductor substrate 12 in the resonance region 22 so that the recessed portion acts as the air gap 20. The recessed portion may fail to penetrate through the semiconductor substrate 12 as illustrated in FIG. 7, or may penetrate through the semiconductor substrate 12 although the illustration thereof is omitted.

As illustrated in FIG. 8, the series resonator and the parallel resonator may have an acoustic mirror 40 under the lower electrode 14 in the resonance region 22 instead of the air gap 20. The acoustic mirror 40 reflects the acoustic wave propagating through the piezoelectric film 16, and includes a film 42 with low acoustic impedance and a film 44 with high acoustic impedance alternately located. The film 42 with low acoustic impedance and the film 44 with high acoustic impedance have film thicknesses of, for example, approximately λ/4 (λ is the wavelength of the acoustic wave). The stacking number of the film 42 with low acoustic impedance and the film 44 with high acoustic impedance can be freely selected.

As described above, the series resonator and the parallel resonator may be a Film Bulk Acoustic Resonator (FBAR) having the air gap 20 under the lower electrode 14 in the resonance region 22, or a Solidly Mounted Resonator (SMR) having the acoustic mirror 40.

### Second Embodiment

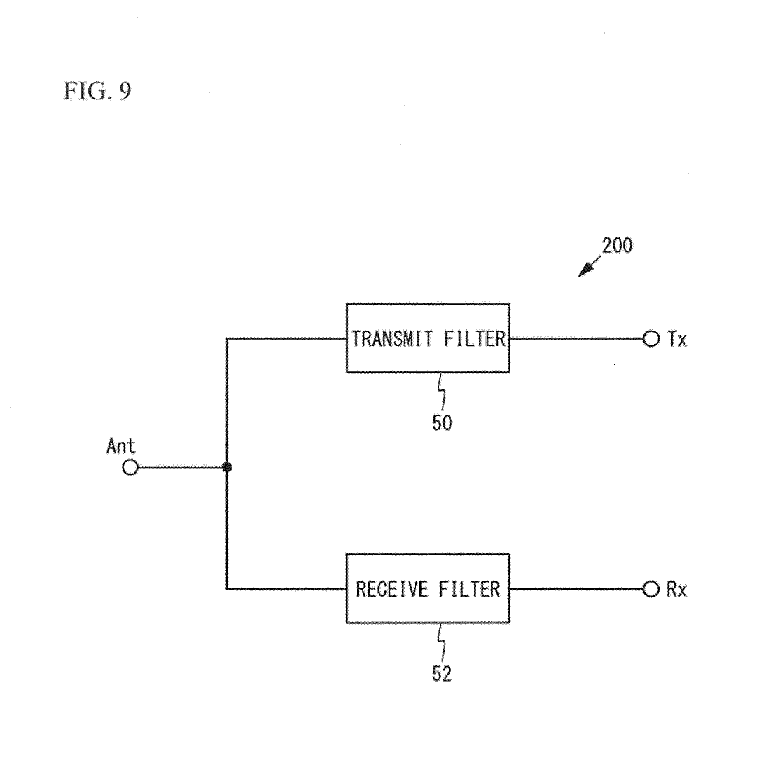

FIG. 9 is a block diagram of a duplexer 200 in accordance with a second embodiment. As illustrated in FIG. 9, the duplexer 200 of the second embodiment includes a transmit filter 50 and a receive filter 52. The transmit filter 50 is connected between an antenna terminal Ant and a transmit terminal Tx. The receive filter 52 is connected between the antenna terminal Ant shared with the transmit filter 50 and a receive terminal Rx.

The transmit filter 50 passes signals in the transmit band to the antenna terminal Ant as a transmission signal among signals input from the transmit terminal Tx, and suppresses signals with other frequencies. The receive filter 52 passes signals in the receive band to the receive terminal Rx as a reception signal among signals input from the antenna terminal Ant, and suppresses signals with other frequencies. The transmit band and the receive band have different frequencies. The duplexer 200 may include a matching circuit (not shown) that matches impedance to output the transmission signal transmitted through the transmit filter 50 from the antenna terminal Ant without leaking to the receive filter 52.

At least one of the transmit filter 50 and the receive filter 52 included in the duplexer 200 of the second embodiment can be the acoustic wave filter 100 of the first embodiment.

### Third Embodiment

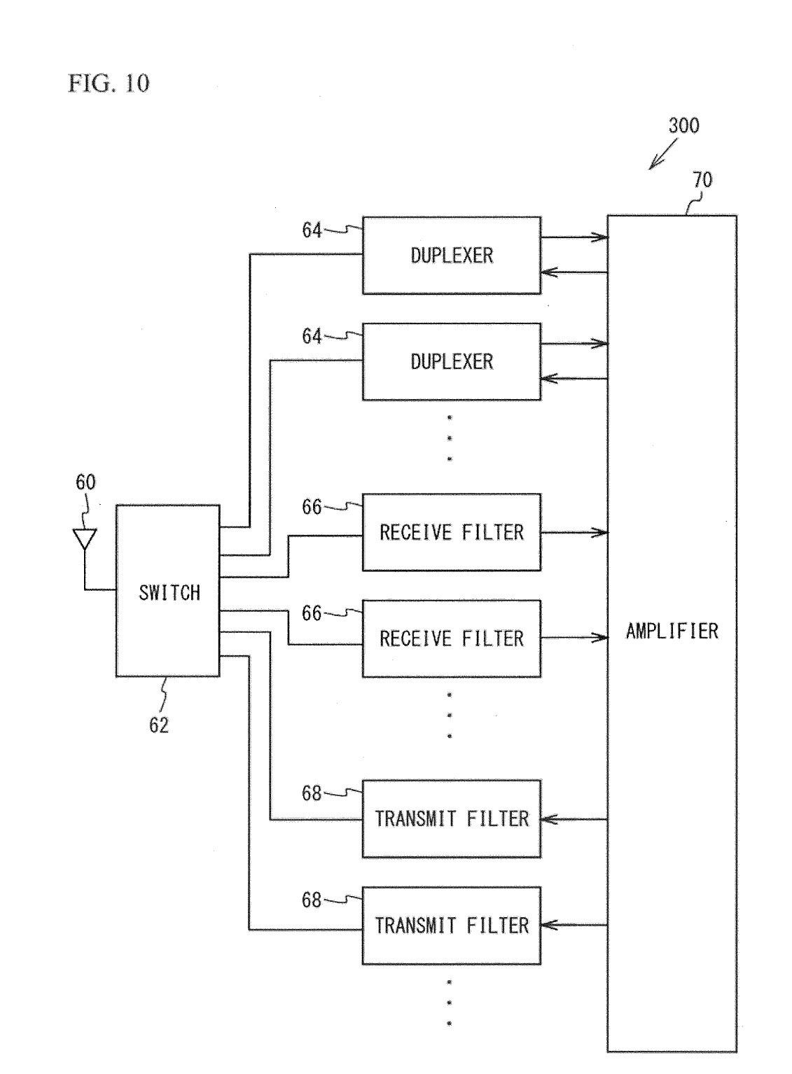

FIG. 10 is a block diagram of a module 300 in accordance with a third embodiment. As illustrated in FIG. 10, the module 300 of the third embodiment includes a switch 62 connecting to an antenna 60, duplexers 64, receive filters 66, transmit filters 68, and an amplifier 70. The module 300 is, for example, an RF module for mobile phones, and supports multiple communication methods such as Global System for Mobile Communication (GSM: registered trademark) and Wideband Code Division Multiple Access (W-CDMA). The antenna 60 transmits/receives transmission signals/reception signals of any of multiple communication methods such as GSM (registered trademark) and W-CDMA.

The duplexers 64, the receive filters 66, and the transmit filters 68 support the corresponding communication methods. The switch 62 selects, in accordance with the communication method of a signal to be transmitted and/or received, the duplexer 64, the receive filter 66, or the transmit filter 68 supporting the communication method, and connects the selected duplexer 64, the selected receive filter 66, or the selected transmit filter 68 to the antenna 60. The duplexers 64, the receive filters 66, and the transmit filters 68 are connected to the amplifier 70.

The amplifier 70 amplifies signals received by the receive filters of the duplexer 64 and the receive filters 66, and outputs them to a processing unit. The amplifier 70 also amplifies signals generated by the processing unit, and outputs them to the transmit filters of the duplexers 64 and the transmit filters 68.

At least one of the receive filters 66 and the transmit filters 68 can be the acoustic wave filter 100 of the first embodiment. At least one of the duplexers 64 can be the duplexer 200 of the second embodiment.

The third embodiment describes a case where the module 300 includes the duplexer 64, the receive filter 66, and the transmit filter 68 as an example, but the module 300 may include at least one of them. The module 300 may be configured not to include the switch 62 and to include the duplexer 64, the receive filter 66, the transmit filter 68, and the amplifier 70, or may be configured not to include the switch 62 or the amplifier 70 and to include the duplexer 64, the receive filter 66, and the transmit filter 68.

Although the embodiments of the present invention have been described in detail, it is to be understood that the various change, substitutions, and alterations could be made hereto without departing from the spirit and scope of the invention.

What is claimed is:

1. A filter comprising:
a substrate;
an input pad;
an output pad;
a ground pad;
a plurality of first acoustic wave resonators formed on the substrate, and connected in series between the input pad and the output pad;
a plurality of second acoustic wave resonators, each comprising:
a piezoelectric film on the substrate;
a lower electrode between the substrate and the piezoelectric film, connected to the ground pad; and
an upper electrode on the piezoelectric film, and connected between an adjacent pair of the first acoustic wave resonators or between one of the plurality of first acoustic wave resonators and one of the input and the output pad.

2. The filter according to claim 1, wherein at least two of the second acoustic wave resonators share a common piezoelectric film.

3. The filter according to claim 1, wherein the ground pad is directly in contact with the substrate.

4. The filter according to claim 1, further comprising:
a first wiring formed on the piezoelectric film, and connects between the second electrode and input pad or output pad,
wherein the input pad and output pad are formed on the piezoelectric film.

5. The filter according to claim 1, further comprising:
a second wiring that connects between the ground pad and the second electrode,
wherein the second wiring is passing through the piezoelectric film in at least part of region.

6. The filter according to claim 1, wherein a space is located below the lower electrode.

7. The filter according to claim 6, wherein the substrate has a concave portion located below the lower electrode, forming an air gap therebetween.

8. The filter according to claim 1, further comprising:
an acoustic mirror located below the at least one of the plurality of first acoustic wave resonator or the plurality of second acoustic wave resonator, the acoustic mirror is structured by at least two layers having different acoustic characteristic each other.

9. A duplexer comprising:
a first filter;
a second filter, the second filter including:
a substrate;
an input pad;
an output pad;
a ground pad;
a plurality of first acoustic wave resonators formed on the substrate, and connected in series between the input pad and the output pad;
a plurality of second acoustic wave resonators, each comprising:
a piezoelectric film on the substrate;
a lower electrode between the substrate and the piezoelectric film, connected to the ground pad; and
an upper electrode on the piezoelectric film, and connected between an adjacent pair of the first acoustic wave resonators or between one of the plurality of first acoustic wave resonators and one of the input and the output pad,
wherein the first filter and the second filter have different passbands.

10. A communication module comprising:
a duplexer having a transmit filter and a receive filter, at least one of the transmit filter and receive filter including:
a substrate;
an input pad;
an output pad;
a ground pad;
a plurality of first acoustic wave resonators formed on the substrate, and connected in series between the input pad and the output pad;
a plurality of second acoustic wave resonators, each comprising:
a piezoelectric film on the substrate;
a lower electrode between the substrate and the piezoelectric film, connected to the ground pad; and
an upper electrode on the piezoelectric film, and connected between an adjacent pair of the first acoustic wave resonators or between one of the plurality of first acoustic wave resonators and one of the input and the output pad,
wherein the transmit filter and the receive filter have different passbands.
